(19) United States
(12) Patent Application Publication
(10) Pub. No.: US 2009/0166718 A1
(43) Pub. Date: Jul. 2, 2009

(54) METHOD OF PREDICTING DRAIN CURRENT IN MOS TRANSISTOR

(76) Inventors: Eun-Jin Lee, Seoul (KR); Seok-Yong Ko, Seoul (KR)

Correspondence Address: SHERR & VAUGHN, PLLC, 620 HERNDON PARKWAY, SUITE 200, HERNDON, VA, 20170, US

(21) Appl. No.: 12/344,409

(22) Filed: Dec. 26, 2008

(30) Foreign Application Priority Data
Dec. 26, 2007 (KR) 10-2007-0137889

(51) Int. Cl. H01L 29/78; G06F 17/50

(52) U.S. Cl. 257/327; 703/14; 257/E29.255

(57) ABSTRACT

Embodiments relate to a method of predicting a drain current that may accurately predict drain current in a linear region, a saturation region, and a breakdown region by modeling a drain current in the breakdown region, in which inconsistency occurs when a drain current depending on a drain voltage is calculated by a related are BSIM3-based modeling scheme, by an expression with a ternary operator, and adding the modeled drain current to the result of a related art BSIM3-based modeling scheme.

The present application claims priority under 35 U.S.C. 119 to Korean Patent Application No. 10-2007-0137889 (filed on Dec. 26, 2007), which is hereby incorporated by reference in its entirety.

### BACKGROUND

FIG. 1 shows a related art metal-oxide semiconductor (MOS) transistor. A MOS transistor may include first impurity (for example, p type) doped region 100 formed in a semiconductor substrate and second impurity (for example, n type) doped source/drain regions 101 in first impurity doped region 100. The second impurity may have an electrical polarity opposite to the first impurity. Channel 102 may be provided and a current may flow between the source and drain by a field effect. A MOS transistor may also include gate oxide film 103 and gate electrode 104 formed on and/or over the semiconductor substrate. In such a MOS transistor, as a drain voltage may increase with a gate voltage maintained constant, a drain current may initially increase linearly (“linear region”). However, when the drain voltage is at a predetermined level or higher, a drain current may not increase any more and may be saturated to a predetermined value (“saturation region”).

FIG. 2 shows a drain voltage-current characteristic curve of a MOS transistor. Reference numeral 200 may be a linear region, and reference numeral 201 may be a saturation region. A drain current may become saturated if, when a drain voltage reaches a specific level, an inversion layer on the side of a drain region disappears. This may be called a pinch-off phenomenon. In this case, a voltage different from a drain voltage may be applied across the channel, and a current flowing through a drain region may depend on an electric field in a depletion layer of the drain region and may be made constant regardless of a drain voltage. If a drain voltage applied to the MOS transistor further increases, as with region 202 shown in FIG. 2, a drain current may rapidly increase. This may be called breakdown. A drain voltage at which a drain current may rapidly increases may be called a breakdown voltage.

Such breakdown may be caused by a breakdown in a PN junction on a side of a drain region. That is, a drain region formed in a semiconductor substrate may be doped with an impurity having a polarity opposite to that of a substrate. A PN junction may be formed between a drain region and a substrate. Electrons accelerated by a strong electric field in a depletion layer at the PN junction may collide against atoms in a depletion layer, and electron-hole pairs may be generated. Generated electrons may be accelerated again. This phenomenon may be repeated, and accordingly a number of electrons (or holes) may rapidly increase. If a breakdown occurs in a MOS transistor, the device may not operate normally and may be put into an abnormal state. Therefore, in developing a semiconductor device, it may be important to accurately understand and predict a relationship between a drain voltage and a drain current related to a breakdown.

Programs that may predict a drain current depending on a drain voltage through a modeling scheme FOR a device, such as a MOS transistor, may be commercially available. For example, SPICE may be an example of a design program and may use BSIM3 (Berkeley Short-channel IgFET Model) to provide modeling. Such modeling may predict a drain current depending on a drain voltage. A related art BSIM3-based modeling scheme may be used to predict only a linear region and a saturation region in the MOS transistor, and may not provide modeling of a breakdown region in which a drain current may rapidly increase.

### SUMMARY

Embodiments relate to a method of predicting a drain current in a MOS transistor that may accurately predict a drain current by adding a drain current in a breakdown region modeled by using a ternary operator to a drain current obtained through BSIM3-based modeling.

Embodiments may provide a method of predicting a drain current that may accurately predict a drain current depending on a drain voltage in a MOS transistor by adding a behavior of a drain current obtained through modeling of breakdown at a PN junction to characteristics of a drain current depending on a drain voltage obtained through a related art BSIM3 modeling scheme by using a ternary operator.

According embodiments, a method of predicting a drain current depending on a drain voltage in a MOS transistor may include at least one of the following. Determining whether or not a drain voltage is higher than a prescribed breakdown voltage. If it is determined that the drain voltage is equal to or lower than the breakdown voltage, setting a drain breakdown current to 1×10⁻¹⁵ A. If it is determined that the drain voltage is higher than the breakdown voltage, setting the drain breakdown current to a third power of a difference between the breakdown voltage and the drain voltage. Adding the drain breakdown current obtained to a drain current obtained through BIMS3-based modeling.

According embodiments, it may be possible to accurately predict characteristics of a drain current depending on a drain voltage in a breakdown region, which may not be predicted through a related art BSIM3-based modeling scheme. Therefore, in designing a new device, accurate information may be provided. In addition, a designer may recognize information indicating that a designed MOS transistor may operate at a voltage higher than a breakdown voltage. As a result, a stable MOS transistor may be designed by taking this operation state of the MOS transistor into consideration.

Embodiments relate to a method that may include at least one of the following: determining whether a drain voltage is higher than a prescribed breakdown voltage; and then setting a drain breakdown current to a first value if the drain voltage is equal to or lower than the prescribed breakdown voltage; and then setting the drain breakdown current to a second value if the drain voltage is higher than the prescribed breakdown voltage; and then adding the drain breakdown current to a drain current.

Embodiments relate to a device that may include at least one of the following: a first impurity doped region formed in a semiconductor substrate; second impurity doped source and drain regions formed in the first impurity doped region; a channel through which a current flows between the source and drain regions by a field effect; a gate electrode formed over the semiconductor substrate; and a gate oxide film formed over the gate electrode, wherein a drain current is predicted by determining whether a drain voltage is higher than a prescribed breakdown voltage, and setting a drain breakdown current to a first value if the drain voltage is equal to or lower than the prescribed breakdown voltage, setting the drain breakdown current to a second value if the drain voltage is higher than the prescribed breakdown voltage, and adding the drain breakdown current to a first drain current.

### DRAWINGS

FIG. 1 shows a structure of a related art MOS transistor.

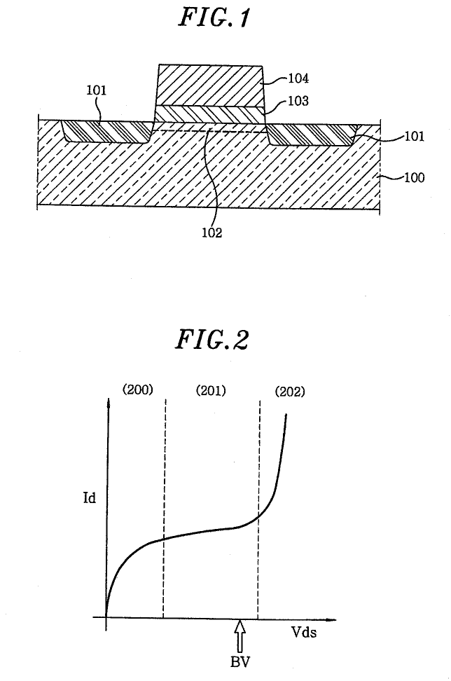

FIG. 2 shows a change in a drain current depending on a drain voltage at a given gate voltage in a MOS transistor.

Example FIG. 3 shows a simulation result of a drain current depending on a drain voltage, according to embodiments.

### DESCRIPTION

According to embodiments, a method of predicting a drain current that may accurately predict drain current in a linear region, a saturation region, and a breakdown region may be provided by modeling a drain current in a breakdown region. In a breakdown region, inconsistency may occur when a drain current, depending on a drain voltage in a MOS transistor, may be calculated by a related art BSIM3-based modeling scheme. The drain current may be modeled by an expression with a ternary operator, and adding the modeled drain current to a result of a related art BSIM3-based modeling scheme.

According to embodiments, a ternary operator may be expressed by Expression 1.

(Condition); (Value 1:Value 2) Expression 1

This expression may return a value 1 if a condition is true and may return a value 2 if a condition is false. According to embodiments, a drain breakdown current may be expressed by Expression 2 with the ternary operator.

Ibv=(Vd>BV); (a X(Vd−BV)ⁿ:1×e⁻¹⁵ A) Expression 2

According to embodiments, in Expression 2, ‘Ibv’ may represent a drain current in a breakdown region (drain breakdown current), ‘Vd’ may represent a drain voltage, ‘BV’ may represent a breakdown voltage, and ‘a’ may represent a proportional constant.

Expression 2 will now be described. According to embodiments, it may be determined whether or not drain voltage Vd is higher than breakdown voltage BV. If drain voltage Vd is equal to or lower than breakdown voltage BV, breakdown may not occur. Accordingly, drain breakdown current Ibv may be substantially zero. Therefore, if a drain voltage is equal to or lower than a breakdown voltage, a drain breakdown current may be set to approximately 1×10⁻¹⁵ A.

If drain voltage Vd is higher than breakdown voltage BV, breakdown may occur. Accordingly a breakdown current Ibv may rapidly increase. According to embodiments, a drain breakdown current Ibv may be set to an n-th power of a difference between drain voltage Vd and breakdown voltage BV.

The factor n may be a value indicating that, when a drain voltage is higher than a breakdown voltage, a drain current may increase. The factor n may be selected from a database in which drain breakdown currents obtained from various MOS transistors on various conditions may be listed. According to embodiments, the factor n may be in a range of 2 to 5.

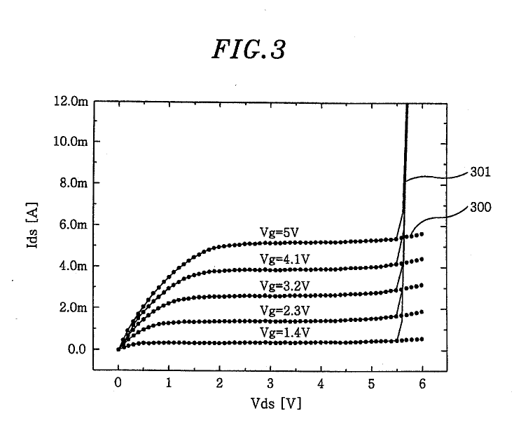

If drain breakdown current Ibv is obtained through the above step, the process may proceed. According to embodiments, a drain breakdown current may be added to a drain current calculated by a related art BSIM3-based modeling scheme. A drain current calculated by a related art BSIM3-based modeling scheme may be consistent with a drain current in the linear and saturation regions 200, 201 of FIG. 2, but may be inconsistent with a drain current in breakdown region 202.

Drain breakdown current Ibv that may be obtained in the above-described manner may be consistent with a drain current in a breakdown region. According to embodiments, by adding drain breakdown current Ibv to a drain current obtained by a related art modeling scheme, behaviors of a drain current in all regions may be accurately predicted.

Example FIG. 3 shows a simulation result of a drain current according to embodiments. According to embodiments, drain current calculation may be performed by using a modeling scheme, such as a library included in the SPICE program, for example.

According to embodiments, a MOS transistor that may be used in a simulation may have a channel length and width are 10 μm and 0.5 μm, respectively, and may have a breakdown voltage of 5.5 V. Gate voltage Vg may be set to 5 V, 4.1 V, 3.2 V, 2.3 V, and 1.4 V. Referring to example FIG. 3, when a related art modeling scheme is used (300), a drain current in the breakdown region may not be expected. According to embodiments, when a modeling scheme according to embodiments is used (301), a drain current may be accurately predicted in the breakdown region where the drain current may rapidly increase when a drain voltage is higher than the breakdown voltage of 5.5 V. A drain current may also be accurately predicted in the linear region where a drain current of a MOS transistor may linearly increase depending on a drain voltage and a saturation region, where the drain current may be saturated to a predetermined value.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
determining whether a drain voltage is higher than a prescribed breakdown voltage; and then
setting a drain breakdown current to a first value if the drain voltage is equal to or lower than the prescribed breakdown voltage; and then
setting the drain breakdown current to a second value if the drain voltage is higher than the prescribed breakdown voltage; and then
adding the drain breakdown current to a drain current.

2. The method of claim 1, wherein the drain current is obtained through Berkeley Short-channel IgFET Model (BIMS3) based modeling for a linear region and a saturation region.

3. The method of claim 1, wherein the first value is approximately 1×10⁻¹⁵ A.

4. The method of claim 1, wherein the drain breakdown current comprises an n-th power of a difference between the drain voltage and the breakdown voltage when the drain voltage is higher than the prescribed breakdown voltage.

5. The method of claim 4, wherein the n-th power is one of 2, 3, 4, and 5.

6. The method of claim 1, wherein the second value is determined by an expression of ‘a’×(Vd−BV)ⁿ, where ‘a’ is a proportional constant, Vd is a drain voltage, and BV is a breakdown voltage.

7. The method of claim 6, wherein n is selected from a database in which drain breakdown currents obtained from at least one MOS transistor are listed.

8. The method of claim 7, wherein the at least one MOS transistor comprises a channel length of approximately 10 μm and a channel width of approximately 0.5 μm.

9. The method of claim 8, wherein the at least one MOS transistor has a breakdown voltage of approximately 5.5 V.

10. The method of claim 6, wherein n is in a range of 2 to 5.

11. A device comprising:
a first impurity doped region formed in a semiconductor substrate;
second impurity doped source and drain regions formed in the first impurity doped region;
a channel through which a current flows between the source and drain regions by a field effect;
a gate electrode formed over the semiconductor substrate; and
a gate oxide film formed over the gate electrode, wherein a drain current is predicted by determining whether a drain voltage is higher than a prescribed breakdown voltage, and setting a drain breakdown current to a first value if the drain voltage is equal to or lower than the prescribed breakdown voltage, setting the drain breakdown current to a second value if the drain voltage is higher than the prescribed breakdown voltage, and adding the drain breakdown current to a first drain current.

12. The device of claim 11, wherein the first drain current is obtained through Berkeley Short-channel IgFET Model (BIMS3) based modeling for a linear region and a saturation region.

13. The device of claim 11, wherein the first value is approximately 1×10⁻¹⁵ A.

14. The device of claim 11, wherein the drain breakdown current comprises an n-th power of a difference between the drain voltage and the breakdown voltage when the drain voltage is higher than the prescribed breakdown voltage.

15. The device of claim 14, wherein the n-th power is one of 2, 3, 4, and 5.

16. The device of claim 11, wherein the second value is determined by an expression of ‘a’×(Vd−BV)ⁿ, where ‘a’ is a proportional constant, Vd is a drain voltage, and BV is a breakdown voltage.

17. The device of claim 16, wherein n is selected from a database in which drain breakdown currents obtained from at least one MOS transistor is listed.

18. The device of claim 16, wherein the channel has a length of approximately 10 μm and a width of approximately 0.5 μm.

19. The device of claim 16, comprising a breakdown voltage of approximately 5.5 V.

20. The device of claim 11, wherein the second impurity has an electrical polarity opposite of the first impurity.
